(19) United States
(12) Patent Application Publication
(10) Pub. No.: US 2009/0310328 A1
(43) Pub. Date: Dec. 17, 2009

(54) FOLDING ELECTRONIC DEVICE AND DEVICE FOR REDUCING UNDESIRED PLAY IN HINGE DEVICE

(75) Inventors: Chikara KOBAYASHI, Kato (JP); Seiji Nagai, Kato (JP); Yutaka Kawahigashi, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/394,241

(22) Filed: Feb. 27, 2009

(30) Foreign Application Priority Data
Jun. 12, 2008 (JP) JP2008-154116

(51) Int. Cl. H05K 7/00

(52) U.S. Cl. 361/809

(57) ABSTRACT

A folding electronic device includes a fixed casing, a movable casing, and a hinge device connecting the fixed casing and the movable casing to allow rotational movement of the movable casing. The movable casing is openable with respect to the fixed casing. The hinge device has an axis extending over a land portion of the fixed casing and a land portion of the movable casing. A projection is provided in any of the following: at least one of end faces of the land portion of the fixed casing and an end face, opposed to one of the end faces, of the land portion of the movable casing. As the movable casing changes from a closed state to an open state, a gap between the projection and an end face opposed to the projection is increased.

### CROSS-REFERENCE TO RELATED APPLICATION

This application is based upon and claims the benefit of priority of the prior Japanese Patent Application No. 2008-154116, filed on Jun. 12, 2008, the entire contents of which are incorporated herein by reference.

### FIELD

The embodiments discussed herein are related to a folding electronic device having a fixed casing and a movable casing rotationally connected to each other by a hinge device with the movable casing openable with respect to the fixed casing, and a device for reducing undesired play in the hinge device of the folding electronic device.

### BACKGROUND

A folding mobile phone has been commonly used in which a fixed casing and a movable casing are rotationally connected to each other by a hinge and the movable casing is structured to be openable with respect to the fixed casing.

With such a folding mobile phone, a hinge has an axis extending over a land portion of a fixed casing and a land portion of a movable casing. A certain amount of clearance (gap) is provided between the land portion of the fixed casing and the land portion of the movable casing, thereby allowing the movable casing to open and close smoothly.

There is proposed and used an open drive mechanism which drives a movable casing to be opened automatically when a fixed casing is held by hand and a button provided on an end of a hinge is pressed with a finger (refer to Japanese Laid-open Patent Publication No. 11-041328). Such an open drive mechanism is usually called one-push open or a one-push open mechanism.

As described above, since a clearance is provided in a hinge of a folding mobile phone, there is undesired play between a fixed casing and a movable casing. Reduction in the clearance results in decreased undesired play between the fixed casing and the movable casing.

However, in the case of employing the open drive mechanism described above, it is necessary to provide a certain amount of clearance in a hinge and reduce rotational resistance in order to realize a smooth opening operation. Because there is a limit to the amount of drive torque of the open drive mechanism.

More specifically, in the case of employing a structure that is opened and closed by a user's hand, it is possible to reduce a clearance and eliminate undesired play. In contrast, in the case of using an open drive mechanism, a clearance is needed, which causes undesired play. In particular, undesired horizontal play (swing) may be noticeable when a movable casing is closed, and an end, which is located further away from a hinge of the movable casing, is moved (swung) quickly and repeatedly from side to side. This degrades the quality of a mobile phone.

### SUMMARY

According to an aspect of the invention, a folding electronic device includes a fixed casing, a movable casing, and a hinge device connecting the fixed casing and the movable casing to allow rotational movement of the movable casing, the movable casing being openable with respect to the fixed casing. The hinge device has an axis extending over a land portion of the fixed casing and a land portion of the movable casing. A projection is provided in any of the following: at least one of end faces of the land portion of the fixed casing and an end face, opposed to one of the end faces, of the land portion of the movable casing. As the movable casing changes from a closed state to an open state, a gap between the projection and an end face opposed to the projection is increased.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a front view illustrating the appearance of a mobile phone according to a first embodiment;

FIG. 2 is a left side view of the mobile phone illustrated in FIG. 1;

FIG. 3 is a front view illustrating a mobile phone that is in a closed position;

FIG. 4 is a left side view illustrating a mobile phone that is in a closed position;

FIG. 5 is a top plan view illustrating a mobile phone that is in a closed position;

FIG. 6 is a perspective view illustrating the vicinity of a land portion of a transmitter-side casing of a mobile phone;

FIG. 7 is a cross sectional top plan view illustrating a land portion of a transmitter-side casing;

FIG. 8 is a front view illustrating a land portion of a transmitter-side casing;

FIGS. 9A-9C are diagrams illustrating a hinge of a mobile phone;

FIG. 10 is an enlarged view of a hinge as viewed from one side of a mobile phone;

FIG. 11 is an enlarged view of a hinge as viewed from the top of a mobile phone;

FIG. 12 is a left side view illustrating a modification of casings of a mobile phone; and

FIGS. 13A and 13B are diagrams illustrating another example of a position where a projection is provided.

### DESCRIPTION OF EMBODIMENT(S)

Preferred embodiments of the present invention will be explained with reference to accompanying drawings.

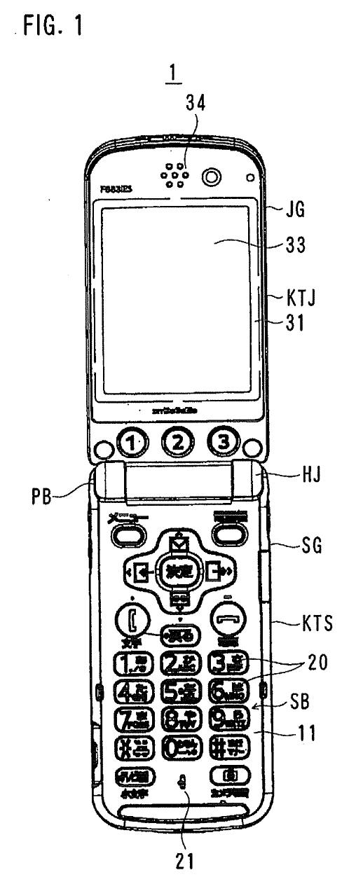

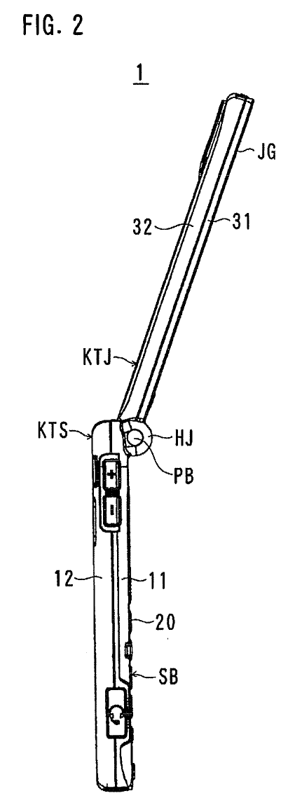

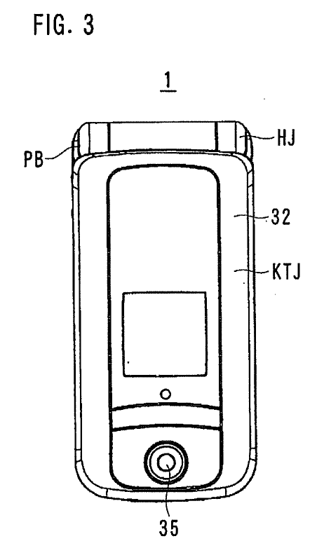

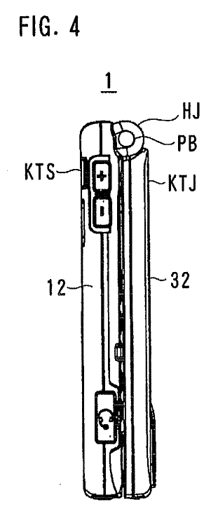

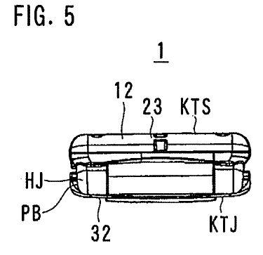

FIG. 1 is a front view illustrating the appearance of a mobile phone 1 according to a first embodiment; FIG. 2 is a left side view of the mobile phone 1 illustrated in FIG. 1; FIG. 3 is a front view illustrating the mobile phone 1 that is in a closed position; FIG. 4 is a left side view illustrating the mobile phone 1 that is in a closed position; and FIG. 5 is a top plan view illustrating the mobile phone 1 that is in a closed position.

As illustrated in FIGS. 1-5, the mobile phone 1 according to this embodiment is a folding mobile phone having a transmitter (fixed side) SG and a receiver (movable side) JG rotationally connected to each other by a hinge HJ. A casing KTS of the transmitter SG includes a front case 11 having, on its surface, an operation portion SB, and a rear case 12 arranged to contact the rear of the front case 11. Each of the front case 11 and the rear case 12 is formed by molding a synthetic resin such as a polycarbonate resin or an ABS resin. A front case 31 and a rear case 32, which are described later, are also formed by molding a resin in a similar manner.

The operation portion SB has various operation buttons 20 arranged to project outwardly through holes formed on the front case 11. The operation buttons 20 are used to enter telephone numbers and other information. The operation portion SB is so configured that contacts or sensors formed on a main circuit board 25, which is described later, detect that the operation button 20 has been pressed. The front case 11 has a voice input hole 21 for transmitting user's voice to a built-in microphone. Referring to FIG. 1, the voice input hole 21 is provided below the operation portion SB.

The rear case 12 is provided with a voice output hole for externally transmitting voice outputted by a speaker, and a strap retaining portion to which a strap is attached (both not illustrated). The rear case 12 has, on its inside, a cell containing portion, and has, on its surface, a detachable cell cover. The front case 11 and the rear case 12 are integral with each other by means of four screws inserted from the rear case 12 and screwed into the front case 11.

A casing KTJ of the receiver JG includes the front case 31, and the rear case 32 arranged to contact the rear of the front case 31. The front case 31 has, on its surface, a main display 33 implemented by a color LCD, and a voice output hole 34 for externally transmitting voice outputted by a built-in speaker for a receiver. Referring to FIG. 1, the voice output hole 34 is provided above the main display 33. The rear case 32 is provided with a lens window 35 of a built-in camera.

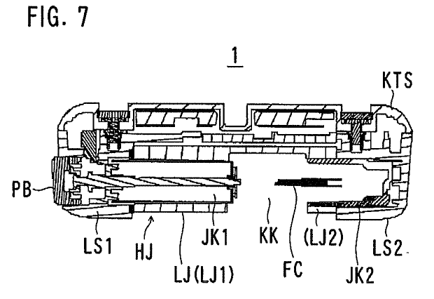

The hinge HJ is provided with an open drive mechanism (one-push open mechanism) JK1 (see FIGS. 7-9C) for driving the casing KTJ of the receiver JG to be opened automatically. As illustrated in FIGS. 7-9C, a push button PB is provided in the left end of the hinge HJ. When a user presses the push button PB with a finger, the open drive mechanism JK1 is started; thereby the casing KTJ of the receiver JG is driven to open and is rotated.

Next, a description is given of a structure of the hinge HJ of the mobile phone 1 and, in particular, an undesired play reduction device GY in the hinge HJ.

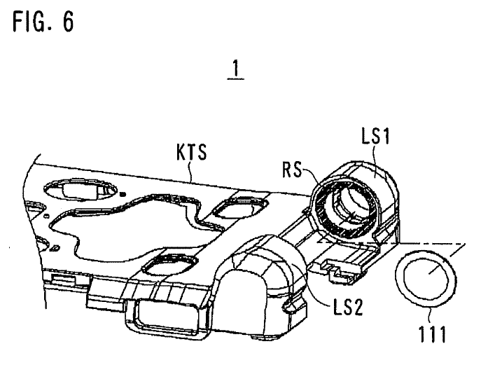

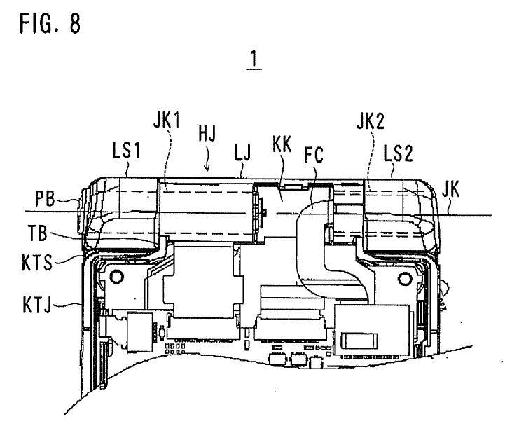

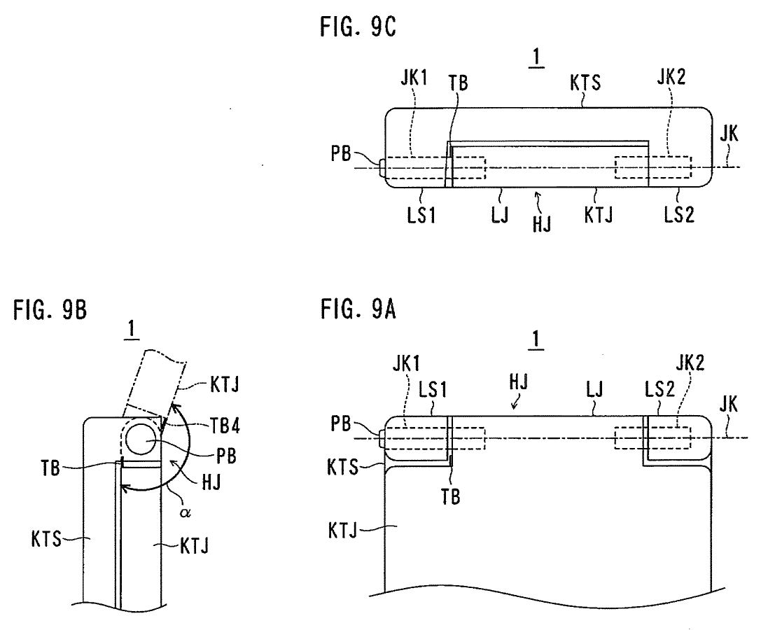

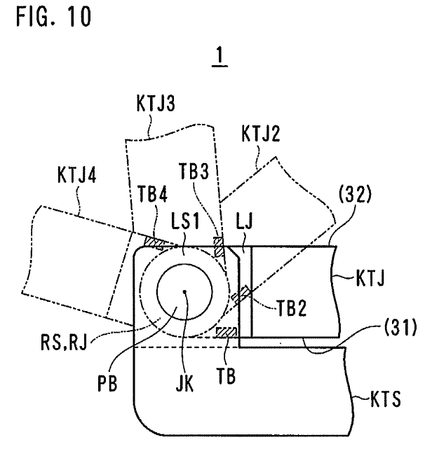

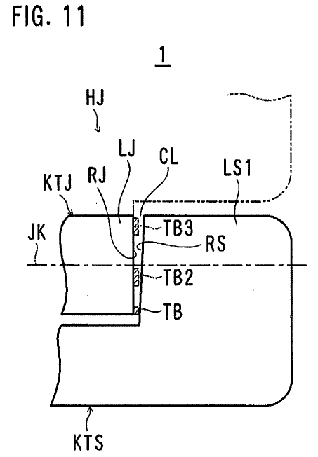

FIG. 6 is a perspective view illustrating the vicinity of a land portion LS of the casing KTS of the transmitter SG of the mobile phone 1; FIG. 7 is a cross sectional top plan view illustrating a land portion LJ of the casing KTS of the transmitter SG; FIG. 8 is a front view illustrating the land portion LJ of the casing KTS of the transmitter SG; FIGS. 9A-9C are diagrams illustrating the hinge HJ of the mobile phone 1; FIG. 10 is an enlarged view of the hinge HJ as viewed from one side of the mobile phone 1; and FIG. 11 is an enlarged view of the hinge HJ as viewed from the top of the mobile phone 1.

FIG. 6 illustrates only the casing KTS; FIG. 7 illustrates the casing KTS to which the open drive mechanism JK1 and the casing KTJ are attached; and FIG. 8 also illustrates the casing KTS to which the open drive mechanism JK1 and the casing KTJ are attached. Referring to FIG. 8, a part of the casing KTJ is cross-sectioned, and a printed circuit board arranged therewithin is partly illustrated.

Further, the shape of the mobile phone 1 illustrated in FIGS. 9A-11 is simplified compared to the mobile phone 1 illustrated in FIGS. 1-8 for easy understanding of the structure and operation of the undesired play reduction device GY in the hinge HJ. Stated differently, the mobile phone 1 illustrated in FIGS. 9A-11 partly differs from the mobile phone 1 illustrated in FIGS. 1-8 in shape and size.

Referring to FIGS. 10 and 11, double-dot-and-dash lines represent the movement of the casing KTJ of the receiver JG from the closed state to the opened state thereof. The position of a projection TB is illustrated in the drawings accordingly in order of TB, TB2, TB3, and TB4.

As illustrated in FIG. 6, a land portion LS1 is provided with a ring-shaped spacer 111. The spacer 111 is formed to have a film-like shape by using a synthetic resin having a lubricating property. The spacer 111 is adhered to an end face RS of the land portion LS1 of the transmitter SG by means of a double-sided tape or an adhesive. In this way, the spacer 111 is disposed between the end face RS of the land portion LS1 of the transmitter SG and an end face RS of the land portion LJ of the receiver JG. When the casing KTJ of the receiver JG is rotated with respect to the casing KTS of the transmitter SG, the spacer 111 reduces friction therebetween. The projection TB is provided outside the outer peripheral of the spacer 111 to avoid interfering with the spacer 111.

Note that the spacer 111 may be disposed between an end face RS of a land portion LS2 of the transmitter SG and an end face RS of the land portion LJ of the receiver JG.

Referring to FIGS. 7 and 8, the land portion LJ of the receiver JG has a cylindrical shape, and is disposed between the land portions LS1 and LS2 of the transmitter SG. A part of the land portion LJ to which the open drive mechanism JK1 is attached, i.e., a land portion LJ1, has a complete cylindrical shape. The land portion LJ1 has, on its inner peripheral surface, a plurality of grooves, in the axial direction, for transmitting rotational torque developed by the open drive mechanism JK1. A drive side of the open drive mechanism JK1 is fitted to the grooves. A part of the land portion LJ to which a shaft member JK2 is attached, i.e., a land portion LJ2, has a cylindrical shape. The land portion LJ2 is partly notched in the circumferential direction thereof to have a slit, thereby enabling a flexible cable FC to be inserted into the land portion LJ2. The land portion LJ2 is pressed in at a tolerance of, for example, approximately 0-0.1 mm in order to prevent the shaft member JK2 from being loosely fitted into the land portion LJ2 due to the slit provided in the land portion LJ2. Note that the shaft member JK2 has a cylindrical shape and is also used as a cable guide.

The appearance of the middle portion of the land portion LJ has a cylindrical shape; however, the inside of the middle portion of the land portion LJ has a notch. The notch is used to insert the flexible cable FC between the transmitter SG and the receiver JG, thereby allowing a variety of signals to be exchanged.

As illustrated in FIGS. 9A-11, the hinge HJ has an axis JK extending over the land portions LS1 and LS2 of the casing KTS of the transmitter SG and the land portion LJ of the casing KTJ of the receiver JG. The projection TB is provided in any one of the following: at least one of the end faces RS of the land portions LS1 and LS2 of the casing KTS of the transmitter SG; and at least one of end faces RJ, which are opposed to the end faces RS of the transmitter SG, of the land portion LJ of the casing KTJ of the receiver JG. In this embodiment, a description is given of a case in which the projection TB is provided in one of the end faces RJ of the land portion LJ of the casing KTJ of the receiver JG.

As clearly illustrated in FIG. 11, a gap CL between the projection TB and the end face RS which is opposed thereto gradually increases as the position of the mobile phone 1 changes from a state in which the casing KTJ of the receiver JG is closed to a state in which the casing KTJ of the receiver JG is opened.

In this embodiment, the end face RS of the land portion LS1 of the transmitter SG is inclined at a predetermined angle P with respect to the axis JK so that the distance between the end face RS and the end face RJ is increased gradually. In short, the end face RS of the land portion LS1 is formed to have an inclination.

The end face RS of the land portion LS2 of the transmitter SG is perpendicular to the axis JK. The end face RJ, which is opposed to the end face RS of the land portion LS2 of the transmitter SG, of the land portion LJ of the receiver JG is also perpendicular to the axis JK. In short, the end face RS of the land portion LS2 and the end face RJ opposed thereto are parallel to each other.

The projection TB is so provided that, in the state in which the casing KTJ of the receiver JG is closed, no gap CL is substantially present between the projection TB and the end face RS opposed thereto.

The end face RJ of the receiver JG is perpendicular to the axis JK, and the projection TB is provided on the end face RJ of the receiver JG. Further, the end face RS of the transmitter SG is so formed that a gap CL between the end face RS of the transmitter SG and the end face RJ of the receiver JG is gradually increased as the distance from the surface of the casing KTS of the transmitter SG is increased in the end face RS.

The projection TB is formed by molding a resin integral with the land portion LJ of the casing KTJ of the receiver JG.

The following is a description of the undesired play reduction device GY.

As clearly illustrated in FIGS. 9A and 9C, the open drive mechanism JK1 that is started by an operation performed by a user and drives the casing KTJ of the receiver JG to be opened is provided on the left side on the axis JK in the drawings. The shaft member JK2 for rotationally connecting the casing KTJ of the receiver JG and the casing KTS of the transmitter SG is provided on the right side on the axis JK in the drawings.

The open drive mechanism JK1 is structured to develop rotational torque by using a restoring force of a coil spring (not illustrated). When the casing KTJ of the receiver JG is closed, a lock is made to prevent the restoring force of the coil spring from acting on the casing KTJ of the receiver JG. When the push button PB is pressed, the lock is released. As a result, the restoring force of the coil spring is exerted on the casing KTJ of the receiver JG and rotational torque is developed to open the casing KTJ.

Examples of the open drive mechanism JK1 include the mechanism disclosed in Japanese Laid-open Patent Publication No. 11-041328 as described earlier and a variety of other known mechanisms. Note that the open drive mechanism JK1 and the push button PB may be provided on the right side of the hinge HJ in, for example, FIG. 9A.

Referring to FIGS. 10 and 11, the projection TB is provided, near the surface of the front case 31, in the end face RJ of the land portion LJ of the receiver JG. When the casing KTJ of the receiver JG is closed, the projection TB has slight contact with the end face RS of the land portion LS1 of the transmitter SG, and the gap CL therebetween is substantially zero. Further, in this state, the surface of the land portion LS2 of the transmitter SG contacts the end face RJ of the land portion LJ of the receiver JG that is opposed to the surface of the land portion LS2.

In this state, the land portion LJ of the receiver JG is sandwiched between the land portions LS1 and LS2 of the transmitter SG with the land portions LS1 and LS2 substantially contacting the land portion LJ, thereby resulting in minimized gap CL. Thus, there are no undesired play in the hinge HJ in the axial direction, and there is little undesired play in the casing KTJ of the receiver JG with respect to the casing KTS of the transmitter SG.

Under this state, even when a force is so applied that an end, which is located further away from the hinge HJ of the casing KTJ of the receiver JG, is moved (swung) quickly and repeatedly from side to side, the casing KTJ of the receiver JG hardly moves (swings) from side to side. Because the land portion LJ of the receiver JG is fixed to the land portions LS1 and LS2 of the transmitter SG with the land portions LS1 and LS2 substantially contacting the land portion LJ. In short, the presence of the projection TB reduces such a quick and repeated movement (swing) from side to side, i.e., undesired horizontal play (swing).

When the push button PB is pressed under such a state, the open drive mechanism JK1 is started to drive the casing KTJ of the receiver JG to rotate the same. This allows the casing KTJ of the receiver JG to open.

Referring to FIG. 10, when the receiver JG is opened to the position denoted by the casing KTJ2, the projection TB is positioned substantially at the middle of the end face RS, in the height direction, of the land portion LS of the transmitter SG, i.e., the position illustrated as the projection TB2. At this time, as illustrated in FIG. 11, the projection TB2 makes no contact with the end face RS of the transmitter SG, thereby resulting in the presence of a gap CL having a certain value.

When the receiver JG is opened to the position denoted by the casing KTJ3, the projection TB is positioned substantially at the upper end of the end face RS, in the height direction, of the land portion LS of the transmitter SG, i.e., the position illustrated as the projection TB3. At this time, as illustrated in FIG. 11, the distance between the projection TB3 and the end face RS of the transmitter SG is further increased, thereby resulting in the presence of a gap CL having a larger value.

Moreover, when the receiver JG is opened to the position denoted by the casing KTJ4, the projection TB is positioned at a much higher end, i.e., the position illustrated as the projection TB4. At this time, the distance between the projection TB4 and the end face RS of the transmitter SG is yet further increased, thereby resulting in the presence of a gap CL having a much larger value.

Incidentally, specific size examples of the receiver JG, the projection TB, and the like are as follows. The land portion LJ of the receiver JG has a thickness (i.e., a diameter) ranging from a couple of millimeters to approximately ten and a couple of millimeters, e.g., of approximately 10 mm. The gap CL between the end face RJ of the land portion LJ of the receiver JG and the end face RS of the land portion LS1 of the transmitter SG is approximately 0.05 to 0.2 mm at the smallest part, e.g., approximately 0.1 mm, and, is approximately 0.3 to 0.5 mm at the largest part, e.g., approximately 0.4 mm. The projection TB has a height ranging from 0.05 to 0.2 mm, e.g., of approximately 0.1 mm. The gap CL between the projection TB and the end face RS of the transmitter SG ranges, depending on the position of the projection TB, e.g., from approximately zero to 0.3 mm, or from approximately zero to 0.45 mm.

As described above, when the casing KTJ of the receiver JG is closed, the projection TB contacts the end face RS. When the casing KTJ of the receiver JG is opened, the distance between the projection TB and the end face RS is increased. Accordingly, when the open drive mechanism JK1 is started, large rotational torque is necessary because some friction exists between the projection TB and the end face RS contacting each other. When the casing KTJ of the receiver JG is rotated slightly, and the distance between the projection TB and the end face RS is increased, the casing KTJ of the receiver JG can be opened completely and smoothly to a predetermined open position even by smaller rotational torque.

In particular, in the case where a coil spring is used for the open drive mechanism JK1, large rotational torque is developed at a time when the open drive mechanism JK1 is started, i.e., upon the initial stage of the open drive. The large rotational torque exceeds the friction existing between the projection TB and the end face RS contacting each other; and therefore it is easy to rotate the casing KTJ of the receiver JG.

Thus, the undesired play reduction device GY is made up of the end face RS having an inclination of the land portion LS1 of the transmitter SG and the projection TB formed on the end face RJ of the receiver JG.

The undesired play reduction device GY according to this embodiment reduces undesired play in the hinge HJ of the folding mobile phone 1. The undesired play reduction device GY can also realize a smooth open drive operation even when the open drive mechanism JK1 is used in the folding mobile phone 1.

In the embodiment described above, the projection TB has a rectangular shape as viewed from the front. However, the projection TB may have a square shape, a sector shape, a circular shape, or a polygonal shape as viewed from the front, instead of the rectangular shape. The top surface of the projection TB may be a plane, a spherical surface, or a conical surface.

### [Modification]

The following is a description of a modification of the mobile phone 1.

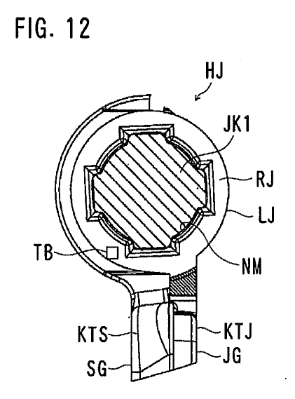

FIG. 12 is a left side view illustrating a modification of the casings KTS and KTJ of the mobile phone 1.

Referring to FIG. 12, the land portion LJ of the casing KTJ of the receiver JG has an inner circumferential surface NM with a groove, and the open drive mechanism JK1 is fitted to the inner circumferential surface NM.

The land portion LJ has, on its end face RJ, the projection TB. As described earlier, when the casing KTJ of the receiver JG is closed (the state illustrated in FIG. 12), the projection TB slightly contacts the end face RS of the land portion LS1 of the transmitter SG (see FIG. 11), and the gap CL therebetween is substantially zero.

Thereby, there are no undesired play in the hinge HJ in the axial direction, thereby resulting in the reduction in undesired play of the casing KTJ of the receiver JG with respect to the casing KTS of the transmitter SG.

Under this state, when the push button provided on the end of the open drive mechanism JK1 is pressed, the open drive mechanism JK1 is started; thereby the casing KTJ of the receiver JG is driven to open and is rotated accordingly.

Referring to FIG. 12, in the case where the projection TB has a rectangular shape, it is, for example, approximately 1 mm wide and approximately 1 mm high.

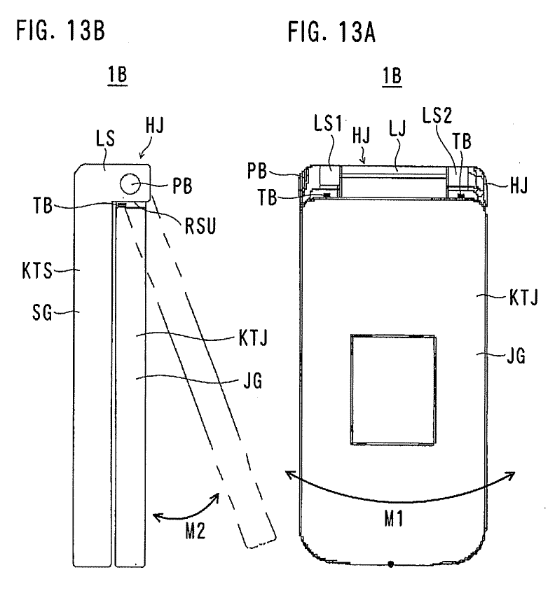

FIGS. 13A and 13B are diagrams illustrating another example of a position where the projection TB is provided. FIG. 13A is a front view of a mobile phone 1B that is in a closed position, and FIG. 13B is a left side view of the mobile phone 1B that is in a closed position.

In the mobile phone 1B illustrated in FIGS. 13A and 13B, the projections TB are provided on both sides of the upper end face of the casing KTJ, other than the land portion LJ, of the receiver JG. The projections TB are so provided that, when the casing KTJ of the receiver JG is closed, they contact or abut inner end faces RSU of the land portions LS1 and LS2 respectively of the casing KTS of the transmitter SG.

Accordingly, under a state where the casing KTJ of the receiver JG is closed, even if a force is applied to swing the casing KTJ of the receiver JG in the directions of arrows M1 (from side to side) of FIG. 13A, there is no undesired play because the two projections TB abut on the end faces RSU of the land portions LS1 and LS2 of the transmitter SG, respectively. Thus, undesired horizontal play (swing) is reduced.

When the casing KTJ of the receiver JG is opened and closed in the directions of arrows M2 (the open and close directions) of FIG. 13B, by, for example, pressing the push button PB of the open drive mechanism JK1, the projections TB do not interfere with other members. Thus, the open/close operation of the casing KTJ of the receiver JG is performed smoothly.

In the embodiments described above, the description is provided of the mobile phones 1 and 1B having the open drive mechanism JK1. The embodiments can also apply to a mobile phone having no open drive mechanism JK1.

In the embodiments described above, the overall structure of the casings KTS and KTJ, the land portions LS and LJ, the projection TB, the hinge HJ, or the mobile phones 1 and 1B or the structures of various portions thereof, the constitution, the shape, the size, the material, the molding method, the production method, the arrangement, the quantity, and the like may be altered as required in accordance with the subject matter of the present invention.

In the embodiments discussed above, the description is provided of the folding mobile phones 1 and 1B. The embodiments can also apply to a folding mobile terminal, a folding information terminal, and a variety of other folding electronic devices.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A folding electronic device comprising:
a fixed casing;
a movable casing; and
a hinge device connecting the fixed casing and the movable casing to allow rotational movement of the movable casing, the movable casing being openable with respect to the fixed casing,
wherein the hinge device has an axis extending over a land portion of the fixed casing and a land portion of the movable casing,
a projection is provided in any of the following: at least one of end faces of the land portion of the fixed casing and an end face, opposed to one of the end faces, of the land portion of the movable casing, and
as the movable casing changes from a closed state to an open state, a gap between the projection and an end face opposed to the projection is increased.

2. The folding electronic device according to claim 1, wherein the projection is so provided that, when the movable casing is closed, no gap is substantially present between the projection and the end face opposed to the projection.

3. The folding electronic device according to claim 2
wherein the end face of the land portion of the movable casing is perpendicular to the axis,
the projection is provided on the end face of the land portion of the movable casing, and
the end face of the land portion of the fixed casing is so formed that a gap between the end face of the land portion of the fixed casing and the end face of the land portion of the movable casing is increased as a distance between the end face of the land portion of the fixed casing and a surface of the fixed casing is increased.

4. The folding electronic device according to claim 2, wherein on the axis is provided an open drive mechanism that is started by an operation performed by a user and drives the movable casing to be opened.

5. The folding electronic device according to claim 2, wherein the projection is formed by molding a resin integral with the land portion of the movable casing.

6. A device for reducing undesired play in a hinge device of a folding electronic device, the folding electronic device including a fixed casing, a movable casing, and the hinge device having an axis extending over a land portion of the fixed casing and a land portion of the movable casing and connecting the fixed casing and the movable casing to allow rotational movement of the movable casing, the movable casing being openable with respect to the fixed casing, the device comprising:
a projection provided in any of the following: at least one of end faces of the land portion of the fixed casing and an end face, opposed to one of the end faces, of the land portion of the movable casing,
wherein, as the movable casing changes from a closed state to an open state, a gap between the projection and an end face opposed to the projection is increased.
